(19) United States
(12) Patent Application Publication
(10) Pub. No.: US 2022/0183189 A1
(43) Pub. Date: Jun. 9, 2022

(54) A SYSTEM AND AN APPLICATION FOR THE REGULATION OF TEMPERATURE IN A SERVER ROOM

(71) Applicant: HEATVENTORS KFT, Mezötúr (HU)

(72) Inventors: Zoltán ANDRÁSSY, Budapest (HU); Farkas Rita ANDRÁSSYNÉ, Budapest (HU)

(73) Assignee: HEATVENTORS KFT, Mezötúr (HU)

(21) Appl. No.: 17/436,290

(22) PCT Filed: Mar. 11, 2020
(86) PCT No.: PCT/HU2020/000009

§ 371 Date: Sep. 3, 2021

(30) Foreign Application Priority Data
Mar. 13, 2019 (HU) P1900078

(51) Int. Cl. H05K 7/20; F24F 5/00

(52) U.S. Cl. CPC H05K 7/20745; H05K 7/20836; F24F 5/0021

(57) ABSTRACT

The object of the invention is a system for regulating the temperature of particularly a server room, where the premises are equipped with an air-conditioning unit. The object of the invention, furthermore, is an application intended to operate the foregoing system, where an external primary circuit, an internal secondary circuit and an air-conditioning unit is operated during the operation of the system. The system according to the invention is characterized in that it furthermore includes a cooling array complete with a thermal regenerator that includes a cooling array complete with a thermal regenerator (T1) that includes an external primary circuit and an internal secondary circuit; where the external primary circuit is primed with a primary transmitting medium which may be circulated with a first fluid machinery, expediently a primary pump (P1), and passes through a primary heat exchanger (H1) unit located outside the premises; the internal secondary circuit is primed with a secondary transmitting medium which may be circulated with a second fluid machinery, expediently a secondary pump (P2), and passes through a secondary heat exchanger (H2) unit located inside the premises; and the external primary circuit and the internal secondary circuit can be controlled independently of each other, by a model suitable for control. The application according to the invention is characterized in that during the operation of the system, the following operating modes alternate: free cooling, case 1 according to the HV model, case 2 according to the HV model or case 3 according to the HV model.

### TECHNICAL FIELD

The object of the invention is a system and procedure for temperature regulation of a server room.

### BACKGROUND ART

A fundamental criterion is that the temperature of server rooms must be kept below a certain temperature to ensure the appropriate operation of data centres. Since servers run continuously on each day of the week and thereby generate heat, they can easily overheat without adequate cooling.

Publication document No. US2018035568 (A1) describes such a cooling solution wherein the cooling system comprises an air handling unit and a direct expansion (DX) unit. The air handling unit comprises a font duct where cool external air enters the air handling unit, and the heated external air exits outwards, and a second duct that enables the server room air to enter the air handling unit and returns the cooled server air into the server room. The air handling unit comprises a heat exchanger to exchange the heat of the server room air with the cool external air, and an adiabatic humidifier in the first duct above the plate heat exchanger to cool the cool external air, in order to increase heat transfer on the plate heat exchanger. The DX unit includes an evaporator which is thermally connected with the second duct.

A characteristic of known solutions is that compressors consume about 80% and fans consume the remaining 20% of energy in a cooling system. The application and system presented in the invention can make state-of-the-art cooling systems more economic than now.

### DISCLOSURE OF INVENTION

The objective of this invention is to make systems currently used for cooling server rooms more cost-efficient.

The solution according to the invention is based on the invention concept that the heat management of the server room permits the cooling processes to be timed so that they are executed with the lowest possible electricity demand subject to the ambient temperature.

The solution according to the invention utilises the natural phenomenon that outside temperature is typically highest during the interval between 11:00 am and 5:00 pm. The effectiveness of known air-conditioning systems is the lowest in this period due to their characteristics. The realisation through the invention is that using a buffer storage, the air conditioner is capable of ensuring the desirable temperature of below 26° C. while operating intermittently, and so the air-conditioning system needs to operate when it is capable of cooling subject to the best efficacy. In the remaining time, the cooling system is enabled to remove an adequate quantity of heat from the premises housing electronic devices without the delivery of external electric power.

The objective of the invention is implemented with a system suitable for regulating the temperature of the server room where the premises are equipped with an air-conditioner; where the system furthermore includes a cooling array complete with a thermal regenerator that includes an external primary circuit and an internal secondary circuit; where the external primary circuit is primed with a primary transmitting medium which may be circulated with a first fluid machinery, expediently a primary pump (P1), and passes through a primary heat exchanger (H1) unit located outside the premises; the internal secondary circuit is primed with a secondary transmitting medium which may be circulated with a second fluid machinery, expediently a secondary pump (P2), and passes through a secondary heat exchanger (H2) unit located inside the premises; and the external primary circuit and the internal secondary circuit can be controlled independently of each other, by a model suitable for control.

In the case of one advantageous form of implementation for the system according to the invention, the external primary heat exchanger is equipped with an external primary air-circulation fan and/or the internal secondary heat exchanger with a secondary air-circulation fan.

In a further advantageous form of implementation for the system according to the invention, the thermal regenerator is a regenerator unit primed with phase change material.

In the case of one advantageous form of implementation for the system according to the invention, the heat transfer medium is aeriform, and the system does not include pumps.

Furthermore, the objective of the invention is achieved with an application which is suitable for operating the system according to the invention, where an external primary circuit, an internal secondary circuit and an air-conditioning unit is operated during the operation of the system; where the following operating modes alternate during system operation:
free cooling,
case 1 according to the HV model,
case 2 according to the HV model or
case 3 according to the HV model.

Here, HV model is understood to mean what is known as a “HeatVentors” model, which will be described at a later point in the description.

In the case of one advantageous variant of the application corresponding to the objective of the invention, the various operating modes alternate based on the temperature forecast, at the time intervals generated with the HV model.

### BRIEF DESCRIPTION OF DRAWINGS

The advantageous design of the system and application according to the invention is described with the help of the enclosed drawings, where

FIG. 1 is the block diagram layout of one advantageous form of implementation of the system according to the invention,

FIG. 2-6 are the coherent logical process flow charts of the application that belongs to the system according to the invention, and

FIG. 7 is a diagram comparing power input required for the system according to the invention and a cooling system without the system according to the invention to operate on an average warm day.

### BEST MODE OF CARRYING OUT THE INVENTION

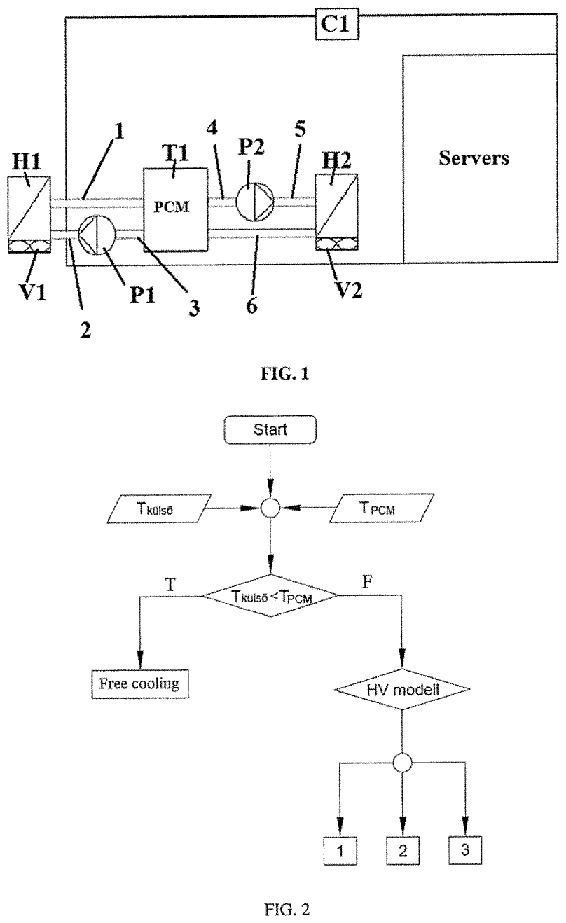

FIG. 1 shows the design of the cooling system and application according to the invention. The system is designed to be parallel to a C1 air-conditioning unit itself known and used, and includes one P1 primary pump, one H1 primary external heat exchanger with one V1 primary external fan, one P2 secondary pump, one H2 secondary internal heat exchanger with one V2 secondary internal fan, moreover one T1 thermal regenerator unit primed with a discretionary PCM phase change material appropriate for the environmental conditions and the thermodynamic purposes. That PCM phase change material may, expediently, be a substance capable of liquid-to-solid phase shifts, which has a high latent heat of fusion, and its phase-shift temperature is selected on the basis of the expected temperature of the server room and average outside temperature, in the range between 15 and 24° C.

The C1 air-conditioning unit, itself known, is thus a part of the system according to the invention, and may also be controlled independently.

The T1 thermal regenerator unit is, expediently, a buffer storage arrangement filled with a PCM phase change material, designed to store heat with one heat-exchange element arranged in the buffer storage and liquid-to-solid phase change material surrounding the heat-exchange element in the storage. The heat exchanger is selected so as to be connected to the cooling system essentially through a primary cooling circuit and a secondary cooling circuit. Naturally, the T1 thermal regenerator unit may also be substituted with any other thermal regenerator unit with similar properties.

One external primary circuit (hereinafter “Circuit 1” on FIG. 2-6) of the system according to the invention includes one H1 primary external heat exchanger and one V1 primary external fan, which are designed either as stand-alone apparatuses or to be inside a single apparatus, e.g. as a thermo ventilator. Pipes 1, 2 and 3 are used to connect the H1 primary external heat exchanger to the heat exchanger—not shown in the figure—of the tank in the T1 thermal regenerator, so that the external primary circuit thus closed is equipped with an additional P1 pump intended to circulate the primary heat-transfer medium inside the external primary circuit.

One internal secondary circuit (hereinafter “Circuit 2” on FIG. 2-6) of the system according to the invention includes one H2 secondary internal heat exchanger and one V2 secondary internal fan, which are designed either as stand-alone apparatuses or to be inside a single apparatus, e.g. as a thermo ventilator. Pipes 4, 5 and 6 are used to connect the H2 secondary internal heat exchanger to the heat exchanger—not shown in the figure—of the tank in the T1 thermal regenerator, so that the internal secondary circuit thus closed is equipped with an additional P2 pump intended to circulate the secondary heat-transfer medium inside the internal secondary circuit.

The circulation of the external primary circuit and the internal secondary circuit is adjustable independently of each other according to desired heat transfer. The primary and secondary heat-transfer medium in the external primary circuit and the internal secondary circuit flows, expediently, in opposing directions.

The primary heat-transfer medium circulated in the external primary circuit may be water or a different coolant, the heat-transfer medium circulated in the internal secondary circuit is expediently water.

Furthermore, the object of this invention is an application, which concerns various advantageous forms of implementation of the system according to the invention. One external primary circuit specified in the description of the system, one internal secondary circuit specified in the description of the system and one C1 air-conditioning unit is controlled during application, where the external primary circuit and the internal secondary circuit are connected to a thermal regenerator unit. The thermal regenerator unit is, expediently, a T1 thermal regenerator primed with PCM phase change material, which has the capacity to store or to ensure the differential of the heat quantity transferred by the external primary circuit and the internal secondary circuit. A C1 air conditioner, itself known, or another heat-control solution, itself known, is furthermore controlled during application.

FIG. 2-6 describe the logical process flow charts of control, where the application controls primary pump P1 and primary external fan V1 in the external primary circuit; secondary pump P2 and secondary internal fan V2 in the internal secondary circuit; moreover air conditioner C1, itself known, subject to the outcome of multiple steps of data comparison.

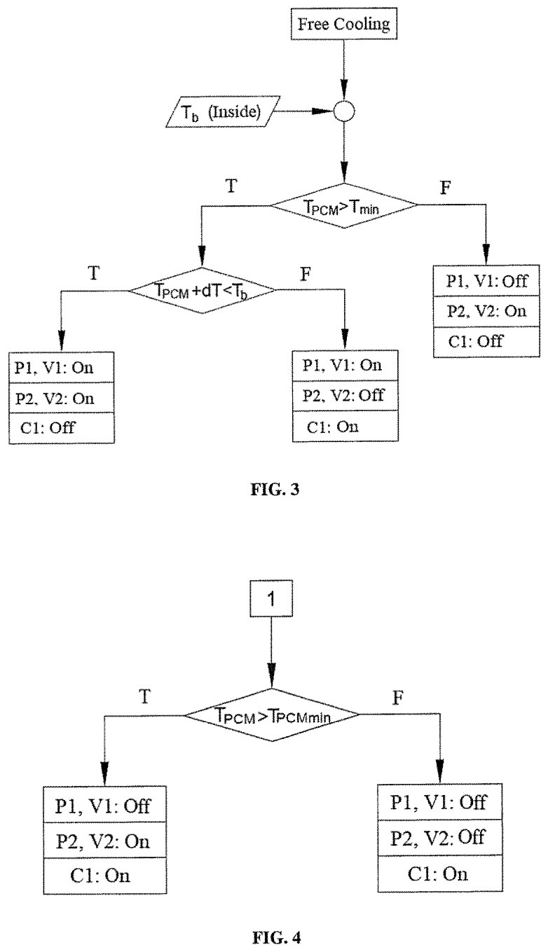

According to the logical process flow chart tree diagram described in FIG. 2, in case the T_{PCM} temperature inside the buffer storage, as calculated on the basis of the HV model using measured values, is greater than a T_{külsõ} temperature outside premises, then the system operates in a specified “free cooling” functionality (see FIG. 3). However, in the case when the T_{PCM} temperature inside the buffer storage is not greater than the T_{külsõ} temperature outside premises, then the system operates in the additional 1 to 3 functionalities selected on the basis of a predefined HV model (the “HeatVentors” model later described by the inventor)(see FIG. 4-6).

FIG. 3 describes the “free cooling” functionality. If the outside-premises temperature T_{külsõ} of the external air found outside the premises is lower than the T_{PCM} temperature, within the buffer storage, of the phase change material that is inside the thermal regenerator T1, and the T_{PCM} temperature inside the thermal regenerator is greater than the Tₘᵢₙ minimum system temperature, then in that case, the external primary circuit is operated by running pump P1, which circulates the primary heat-transfer medium located in the external primary circuit, and its corresponding V1 primary air-circulation fan, thereby stockpiling the cooling capacity of external air outside the premises. At this point, external primary fan V1 delivers a flow of outside air through external primary heat exchanger H1, external primary heat exchanger H1 processes the coolant arriving from the regenerator through pipeline 2 and 3, which is returned to the buffer storage, in cooled state, through pipeline 1, where it chills the PCM phase change material.

In case the T_{PCM} temperature of thermal regenerator T1 inside the buffer storage reaches the Tₘᵢₙ minimum temperature value of the system, which—in the case of one advantageous form of implementation—is expediently e.g. 14° C., then the further cooling of the system stops, and pump P1 is deactivated, along with its corresponding primary air-circulation fan V1. At this point, the phase change material in regenerator T1 is in solid state, and is therefore suitable for cooling. Pump P2 in the secondary circuit and secondary air-circulation fan V2 is switched on, moreover air conditioner C1 is deactivated, since cooling is provided using regenerator T1. The advantageous minimum 14° C. has been determined empirically through condensation in the system used during application.

Regulation of the internal secondary circuit needs the Tb internal temperature of the room, as well as the T_{PCM} temperature of the T1 thermal regenerator in the buffer storage, and a predefined dT temperature differential. The advantageous value of the dT temperature differential is 1-5° C., more expediently 3° C. If the temperature of the PCM phase change material is lower than the interior temperature of the room by a system-dependent dT temperature differential, then the T1 thermal regenerator is able to perform cooling. The C1 air-conditioning unit is deactivated, while the secondary circuit is enabled. The P2 secondary pump in the activated secondary internal circuit circulates the coolant of the secondary internal circuit, meanwhile, internal secondary air-circulation fan V2 draws warm air from the premises through secondary internal heat exchanger H2. The heat exchanger cools air from the room, while expending the cooling capacity of the T1 regenerator.

In case thermal regenerator T1 is no longer able to provide cooling, in other words, the dT temperature differential is not adequate, the secondary circuit is deactivated, and the air conditioner is switched on to perform cooling.

As soon as the T_{külsõ} outside temperature becomes too high for the further cooling of the PCM phase change material in thermal regenerator T1, the system switches from the “free cooling” to one of operating modes according to case 1-3, as selected by the HV model.

FIG. 4 to 6 present functions 1-3 that the HV model can select. The HV model is an algorithm that can be used to calculate the output of a thermal energy buffer storage across the entire spectrum, subject to the temperature and mass flow of the inlet heat transfer medium, expediently water, as well as the state (temperature and phase) of the PCM phase change material in thermal regenerator T1. For thermal regenerator T1, which contains the PCM phase change material, that output is greatly affected by the PCM phase change material's state of matter and the magnitude of the corresponding variable thermal resistances. The HV model is intended to allow calculating momentary buffer storage capacity at every time point. The model can therefore be used to calculate momentary cooling capacity in the T1 regenerator at every time point.

Using the buffer storage's axes of symmetry, the process must be started with the thermal analysis of the smallest elementary entity, subject to the following criteria:
The exchange of heat and substance between the elements is discarded
The temperature of the buffer storage medium and the heat transfer medium is constant within a single elementary entity
The heat transfer coefficients are constant
Continuity is asserted for the transmitting medium
The elementary entity is free of heat sources
Energy stored by the buffer storage wall is negligible
   The differential equation that describes heat exchange is:

$${\dot{m}}_{water} \cdot {c}_{p , water} \cdot {T}_{water} - {\dot{m}}_{water} \cdot {c}_{p , water} \cdot ( {T}_{water} + \frac{\partial {T}_{water}}{\partial x} \cdot Δ x ) = k \cdot {D}_{tube} \cdot π \cdot Δ x \cdot Δ {T}_{log} + {m}_{tube} \cdot {c}_{p , steel} \cdot \frac{\partial {T}_{tube}}{\partial τ} . \qquad ( 1 )$$

Based on the numbering below, its elements express the following:

(I)−(II)=(III)+(IV):
(I) is the enthalpy flow rate of the heat recovery medium at the inlet of the Δx length pipe section,
(II) is the enthalpy flow rate of the heat recovery medium at the outlet of the Δx length pipe section,
(III) is the thermal power attained by the phase change material,
(IV) is the energy stored by the material of the heat exchanger.
   Subsequently to the criteria, Formula 1 may be reduced as follows:

$$\begin{matrix}{\dot{m}}_{water} \cdot {c}_{p , water} \cdot {T}_{water} - {\dot{m}}_{water} \cdot {c}_{p , water} \cdot ( {T}_{water} + \frac{\partial {T}_{water}}{\partial x} \cdot Δ x ) = k \cdot {D}_{tube} \cdot π \cdot Δ x \cdot ( {T}_{water} - {T}_{PCM} ) , & ( 2 ) \\ \frac{\partial {T}_{water}}{\partial x} = \frac{- k \cdot {D}_{tube} \cdot π}{{\dot{m}}_{water} \cdot {c}_{water}} \cdot ( {T}_{water} - {T}_{PCM} ) . & ( 3 )\end{matrix}$$

After introducing a normal transmission unit that is based on the temperature differential:

$$NTU = \frac{k \cdot {D}_{tube} \cdot π \cdot L}{{\dot{m}}_{water} \cdot {c}_{p , water}} . \qquad ( 4 )$$

By substituting it in Formula 3:

$$\begin{matrix}\frac{\partial {T}_{v}}{\partial x} = - \frac{NTU}{L} \cdot ( {T}_{water} - {T}_{PCM} ) , & ( 5 ) \\ \frac{{T}_{water}^{n - 1} - {T}_{water}^{n}}{{T}_{water}^{n - 1} - {T}_{PCM}^{n - 1}} = 1 - {e}^{- {NTU}_{n}} & ( 6 )\end{matrix}$$

After sorting, the following formula will result in the temperature of water exiting the respective pipe-coil loop:

T_{water}ⁿ=T_{water}ⁿ⁻¹−(T_{water}ⁿ⁻¹−T_{PCM}ⁿ⁻¹)·(1−e^{-NTU}). (7)

The power output of the water is:

\dot{Q}_{water}=\dot{m}_{water}·c_{water}·(T_{water}ⁿ−T_{water}ⁿ⁻¹). (8)

Energy stored in one time increment is:

$${\dot{Q}}_{stored} = {k}_{l} \cdot {A}_{l} \cdot ( {T}_{water} - {T}_{PCM} ) = \frac{{m}_{PCM} \cdot {c}_{PCM} \cdot ( {T}_{PCM}^{i + 1} - {T}_{PCM}^{i} )}{τ} . \qquad ( 9 )$$

Index i differentiates among heat currents from the multiple sources.

Dimensioning methods, themselves known, are available for the design state; to this end, the buffer storage must be split into elementary sections, and iterations performed. Changes in operational circumstances are hard to follow using such a model, yet that is necessary on account of proper regulation and tracking. The goal is to find the \dot{Q}(τ)=f(\dot{m}_{water}, T_{water entry}, T_{PCM}) equation.

The thermal power of the elementary entity may be calculated using the correlations described earlier. Conducting a temporal and spatial simulation permits calculating the performance of the entire buffer storage as a function of time.

Practical experience shows that the value of specific thermal power is independent of the temperature of water entering the tank.

$${\dot{q}}_{storage} = \frac{{\dot{Q}}_{storage}}{{T}_{water} - \overline{{T}_{PCM}}} \qquad ( 10 )$$

The model is suitable for running a longer time-month or year-long-simulation over short worktime, subject to a constant mass flow. The performance of the buffer storage by time is recalculated as mass flow changes, or multiple performance diagrams are generated, and the performance that can be read from those is interpolated using means that are themselves known.

The model may thus be adapted to a system, where its performance is easy to calculate whether as a heat consumer or a heat producer, while energy saved by the system can be calculated through heat accumulation.

In a cooling system, the outside temperature forecast can be used to generate the efficiency of the cooling system and cooling need. By using these and the HV model, the system is enabled to calculate cooling need over the next 24 hours and the efficiency of the air conditioner, even with low calculation capacities. This allows determining, with methods themselves known, when to switch over to the various operational states.

Thereby the HV model operates the system essentially differently in operational stages 1, 2 and 3. In each of the operating modes, it is valid that the T_{külsõ} outside temperature is higher than the T_{PCM} buffer storage temperature, thereby the option of “free cooling” is not available, and the external primary circuit is deactivated.

Operating mode 1 (FIG. 4) is active in the case when the efficiency of the air conditioner is best. That usually occurs in the evening and dawn hours. That time interval is always a function of outside temperature, it does not correspond to the same period in each case nor is the length of the interval identical every time, therefore lacking the appropriate model, regulation based on time is not possible with satisfactory accuracy.

T_{PCMmin} is the lowest temperature of phase change hysteresis, and below that temperature, the PCM phase change material is completely solid. The value of T_{PCMmin} is the thermodynamic property of the given PCM phase change material, e.g. 19° C.

The efficiency of air conditioner C1 is highest in this period, therefore operating air conditioner C1 is cost-effective at that time, thus it is by all means powered on in this case. Since “free cooling” cannot be used at this time due to outside temperature not being sufficiently low, therefore the buffer storage is primed using the air conditioner, in other words, the PCM phase change material in thermal regenerator T1 is frozen. Cooling with air conditioner C1 is not cost-efficient relative to “free cooling”, so it is not worth chilling the PCM phase change material inside thermal regenerator T1 to below its solidification point. If the temperature of the PCM phase change material, in this case, the temperature of the PCM phase change material at the warmest point of the buffer storage, is higher than T_{PCMmin}, then the buffer storage is not yet fully primed, therefore the internal secondary circuit is powered on, and thermal regenerator T1 is cooled with the air conditioner. Otherwise, the buffer storage is fully primed, therefore the internal secondary circuit is powered off.

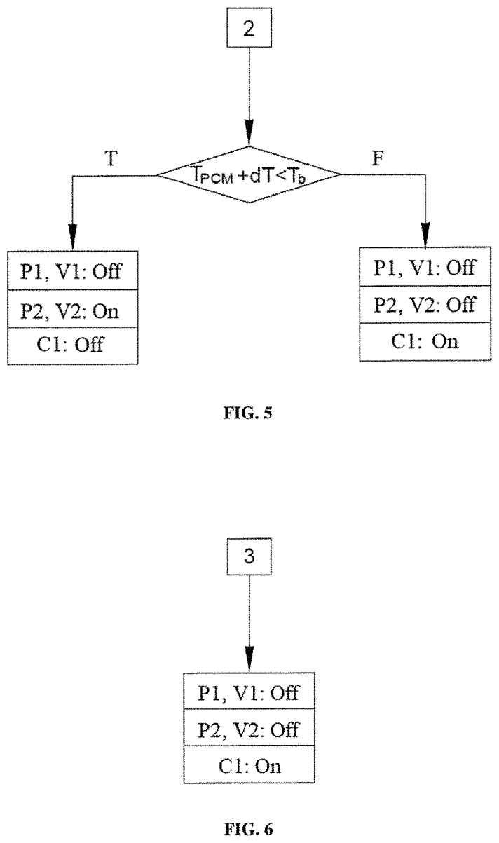

FIG. 5 describes operating mode 2. During the day, this is the period when the efficiency of the air conditioner is worst, and it generally occurs during daytime. The time interval is always a function of outside temperature, it does not correspond to the same period in each case nor is the length of the interval identical every time, therefore regulation based on time is not possible with satisfactory accuracy.

Outside temperature is highest in this case, therefore this is when the efficiency of air conditioner C1 is worst, and therefore cooling is performed by thermal regenerator T1 for as long as a driving force provided by a dT temperature differential allows it to do so. For this case, we need the Ta internal temperature of the room in order to regulate, along with the T_{PCM} temperature of the PCM phase change material at the coldest point of regenerator T1, and a temperature differential preset depending on system dimensioning: dT. The advantageous value of the dT temperature differential is between 1-5° C., more expediently 3° C. If the temperature of the PCM phase change material is lower than the interior temperature of the room by a system-dependent dT temperature differential, then the T1 thermal regenerator is able to perform cooling. The C1 air-conditioning unit is deactivated, while the secondary circuit is enabled so that the regenerator can perform cooling. Otherwise, thermal regenerator T1 is no longer able to provide cooling, so the secondary circuit is deactivated, and the air conditioner is switched on to perform cooling. That will not only eliminate operation with the worst efficiency, but also serve the performance peak, therefore dimensioning air-conditioning unit C1 to a smaller scale will suffice.

Operating mode 3 is possible in the case of a transitional state, which is illustrated in FIG. 6. In this case, the efficiency of air-conditioning unit C1 is not sufficiently high for using it to prime the buffer storage, nor is it low enough to need to be switched off. It is not worth cooling the room with the buffer storage, since buffer storage capacity is reserved for case 2. There is no “free cooling”, so the external primary circuit is powered off, thermal regenerator T1 is not primed nor is it discharged, therefore the internal secondary circuit is also switched off. Air-conditioning unit C1 performs cooling on its own, therefore air-conditioning unit C1 is powered on.

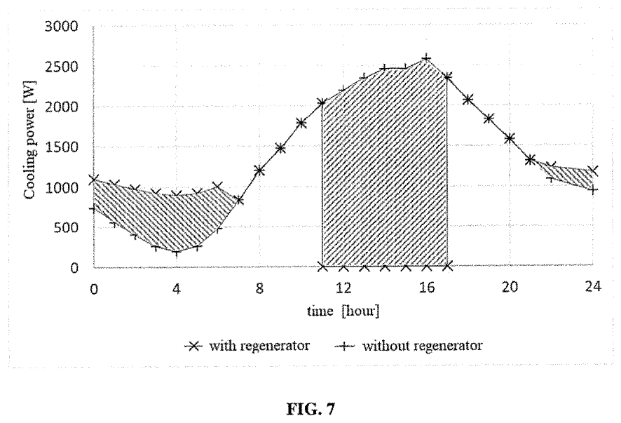

FIG. 7 illustrates the comparison of one optimal operation of the HV model and one C1 air-conditioning unit continuously running according to the state of the art. The figure shows that the power consumption of air-conditioning unit C1 is different during various times of day, so, in order to eliminate that, it is possible to prime thermal regenerator T1 more cost-efficiently during some times of day, while at other times, it is utilising the cooling capacity of thermal regenerator T1 that is more cost-efficient.

The benefit of the system and application according to the invention is that by installing the system and using the application, it is possible to reduce the power demand, and thereby the cost, of thermal management in server rooms.

Another benefit of the solution according to the invention is that it can be combined with any existing C1 air-conditioning unit or other parallel cooling solution, and installed and used for the cooling of server rooms, as well as for any other cooling system whatsoever.

### LIST OF REFERENCE NUMERALS

1—pipeline
2—pipeline
3—pipeline
4—pipeline
5—pipeline
6—pipeline
C1—air-conditioning unit
H1—primary external heat exchanger
H2—secondary internal heat exchanger
P1—primary pump
P2—secondary pump
T1—thermal regenerator
PCM—phase change material
V1—primary air-circulation fan
V2—secondary air-circulation fan

1. A system for regulating the temperature of particularly a server room, where the premises are equipped with an air-conditioning unit (C1), characterized in that the system furthermore includes a cooling array equipped with a thermal regenerator (T1) that has an external primary circuit and an internal secondary circuit, where
the external primary circuit is primed with a primary transmitting medium which may be circulated with a first fluid machinery, expediently a primary pump (P1), and passes through a primary heat exchanger (H1) unit located outside the premises,
the internal secondary circuit is primed with a secondary transmitting medium which may be circulated with a second fluid machinery, expediently a secondary pump (P2), and passes through a secondary heat exchanger (H2) unit located inside the premises,
and the external primary circuit and the internal secondary circuit can be controlled independently of each other, by a model suitable for control.

2. The system according to claim 1, characterized in that the external primary heat exchanger (H1) is equipped with an external primary air-circulation fan (V1) and/or the internal secondary heat exchanger (H2) with a secondary air-circulation fan (V2).

3. The system according to claim 1, characterized in that the thermal regenerator (T1) is a regenerator (T1) unit primed with phase change material (PCM).

4. The system according to claim 1, characterized in that the heat transfer medium is aeriform, and the system does not include pumps (P1, P2).

5. An application intended to operate the system according to claim 1, where an external primary circuit, an internal secondary circuit and an air-conditioning unit (C1) is operated during the operation of the system, characterized in that the following operating modes alternate during system operation:
free cooling,
case 1 according to the HV model,
case 2 according to the HV model or
case 3 according to the HV model model.

6. The application according to claim 5, characterized in that the various operating modes alternate based on the temperature forecast, at the time intervals generated with the HV model.

7. The system according to claim 2, characterized in that the thermal regenerator (T1) is a regenerator (T1) unit primed with phase change material (PCM).

8. The system according to claim 2, characterized in that the heat transfer medium is aeriform, and the system does not include pumps (P1, P2).

9. The system according to claim 3, characterized in that the heat transfer medium is aeriform, and the system does not include pumps (P1, P2).
